(19) United States
(12) Patent Application Publication
(10) Pub. No.: US 2019/0330075 A1
(43) Pub. Date: Oct. 31, 2019

(54) LEAD-FREE DOUBLE PEROVSKITES FOR PHOTOVOLTAIC APPLICATIONS

(71) Applicants: Washington University, St. Louis, MO (US); Traid National Security, LLC, Los Alamos, NM (US)

(72) Inventors: Rohan Mishra, St. Louis, MO (US); Arashdeep Singh Thind, St. Louis, MO (US); Ghanshyam Pilania, Los Alamos, NM (US); Shalinee Kavadiya, St. Louis, MO (US); Pratim Biswas, St. Louis, MO (US)

(21) Appl. No.: 16/399,001

(22) Filed: Apr. 30, 2019

Related U.S. Application Data
(60) Provisional application No. 62/664,582, filed on Apr. 30, 2018.

(51) Int. Cl. C01G 29/00; H01L 31/032; H01L 31/04

(52) U.S. Cl. CPC C01G 29/006; H01L 31/032; C01P 2002/72; C01P 2002/34; C01P 2006/40; H01L 31/04

(57) ABSTRACT

The present disclosure is directed to double perovskite oxide semiconductors. In particular, the present disclosure is directed to lead-free double perovskite oxides that provide excellent stability and are used, for example, as photovoltaic materials.

### CROSS-REFERENCE TO RELATED APPLICATION

This application claims the benefit of U.S. Provisional Patent Application Ser. No. 62/664,582, filed Apr. 30, 2018, the entire contents of which are incorporated herein by reference.

### STATEMENT REGARDING FEDERALLY SPONSORED RESEARCH & DEVELOPMENT

This invention was made with government support under subcontract DE AC36-08G028308 awarded by U.S. Department of Energy and under grant DMR 1806147 awarded by the National Science Foundation. The government has certain rights in the invention.

### BACKGROUND OF THE DISCLOSURE

The field of the disclosure relates generally to lead-free double perovskites. More specifically, this application relates generally to stable lead-free double perovskites for use in semiconductor and photovoltaic applications such as solar cells.

Solar energy is a highly regarded alternative energy source. A solar cell is a device that converts light energy into electrical energy, and does not give off any greenhouse gases such as carbon dioxide or other undesirable substances when producing energy. Solar cells are based on the principles of the photovoltaic effect of semiconductor materials to convert light energy into electrical energy. Specifically, when light is incident upon the semiconductor material, photons are absorbed and give rise to electron-hole pairs in the semiconductor material. The electrons and holes are transported to the opposite electrodes respectively by the internal electric field, resulting in a voltage. When the two electrodes are connected to an external circuit, a current is generated.

Organic-inorganic lead-halide perovskites have emerged as a class of semiconductors with applications in solar cells, optoelectronics devices and photocatalysis. However, lead-halide perovskites suffer from poor environmental stability (reactivity), poor device stability under electric field, photodegradation, and in some cases, thermodynamic instability. These stability issues combined with the highly toxic nature of lead makes them unlikely candidates for widespread commercial applications. Therefore, there is a need to replace toxic lead-halide perovskites with benign and stable materials without compromising the properties that make them attractive semiconductors for a variety of applications.

There is an ongoing search to find stable and environmentally benign alternatives to lead-halide perovskites. The substitution of lead with lighter group IV cations, such as Sn and Ge, has yielded limited success due to the instability of +2 oxidation state in these cations. The heavy Pb²⁺ cation with its occupied 6 s² lone-pair electrons is pivotal to attain an electronic structure that is optimized for solar cell applications. The delocalized nature of the Pb 6 p states leads to a highly dispersed conduction band with a low effective mass of the electrons. The valence band edge is formed of antibonding states of Pb 6 s² hybridized with the p-states of the halide anions, which reduces the effective mass of the holes. Moreover, the presence of antibonding states at the valence band edge results in defect levels that are either shallow or lie within the bands for point defects with low formation energy. The Pb 6 s² lone-pair electrons also result in a large dielectric constant that improves carrier lifetimes by effectively screening charged defects and by reducing the exciton binding energies. Overall, the combination of a large dielectric constant and the presence of antibonding states at the valence band edge have been attributed to the remarkable defect-tolerance that these lead-halide perovskites exhibit.

To find replacements for the unstable and toxic lead-halide perovskite semiconductors without compromising their performance, specific properties are required: a high optical absorbance in the visible range and a large carrier lifetime. These properties arise from: 1) an optimal band gap with a steep absorption edge that can absorb a large portion of the solar spectrum, 2) a small effective mass of electrons and holes, and 3) a “defect-tolerant” electronic structure. At the structural level, these properties are dictated by the heavy lead (Pb²⁺) cation present within the perovskite framework. Thus, there is a need to develop a lead-free material having improved properties for use in semiconductor and photovoltaic applications.

### BRIEF DESCRIPTION OF THE DISCLOSURE

In one embodiment of the present disclosure, a lead-free double perovskite having a formula of AA′BB′Oₙ is disclosed, wherein A and A′ are the same or are different and are selected from the group consisting of alkali metals, alkaline earth metals, actinides, transition metals, post-transition metals and metalloids; B and B′ are different and selected from the group consisting of alkali metals, alkaline earth metals, actinides, transition metals, post-transition metals and metalloids; and n is a real number from 2 to 6.

In another embodiment of the present disclosure, a semiconductor comprising a lead-free double perovskite is disclosed. The perovskite has the formula AA′BB′Oₙ wherein A and A′ are the same or are different and are selected from the group consisting of alkali metals, alkaline earth metals, actinides, transition metals, post-transition metals and metalloids; B and B′ are different and selected from the group consisting of alkali metals, alkaline earth metals, actinides, transition metals, post-transition metals and metalloids; and n is a real number from 2 to 6.

In yet another embodiment of the present disclosure, a photovoltaic cell comprising a lead-free double perovskite is disclosed. The perovskite has the formula AA′BB′ₙ wherein A and A′ are the same or are different and are selected from the group consisting of alkali metals, alkaline earth metals, actinides, transition metals, post-transition metals and metalloids; B and B′ are different and selected from the group consisting of alkali metals, alkaline earth metals, actinides, transition metals, post-transition metals and metalloids; and n is a real number from 2 to 6.

### DESCRIPTION OF THE DRAWINGS

FIGS. 1A and 1B illustrate the structure of a double perovskite having layered ordering at the A-site and rock-salt ordering at the B-site (FIG. 1A), and the variation of octahedral factor with a tolerance factor for previously synthesized AA′B′BiO₆ (from ICSD) and for the screened hypothetical compounds conforming to the experimental trend line within the region of confidence (FIG. 1B).

FIGS. 2A, 2B and 2C illustrate the variation of formation enthalpy (ΔAH_{f}) with the tolerance factor for AA′B′BiO₆ compounds with a cubic double perovskite structure (FIG. 2A), the ground state structure with octahedral rotations (FIG. 2B), and variation of the scaled HSE+SOC band gap with formation enthalpy for the ground state structures of stable AA′B′BiO6 compounds (FIG. 2C). The compounds with formation enthalpy lower than 100 meV/atom are considered experimentally formable. The marker 1 in FIGS. 2A, 2B and 2C corresponds to KBaTeBiO₆.

FIGS. 3A and 3B illustrate the calculated band structure (FIG. 3A) and atom-projected density of states (DOS/atom) for KBaTeBiO₆ (FIG. 3B).

FIGS. 4A and 4B illustrate the XRD patterns for KBaTeBiO₆, where the top and middle layers are the XRD patterns for samples annealed at 600 and 500° C., respectively, while the bottom layer is the simulated XRD pattern of the optimized structure from DFT (FIG. 4A), and the absorption spectrum of KBaTeBiO₆ measured using a UV-vis spectrophotometer (FIG. 4B). The inset shows the Tauc plot with an estimated indirect band gap of 1.5 eV. The bottom left corner of FIG. 4B shows an image of the as-synthesized KBaTeBiO₆ powder.

FIG. 5 illustrates the calculated band structure (left) and DOS (right) for the cubic double perovskite SrBaVBiO₆ calculated using PBE.

FIG. 6 illustrates an exemplary embodiment of a comparison of the absorption spectra of cubic Cs₂AgBiBr₆ and KBaTeBiO₆ calculated using HSE06 functional with spin-orbit coupling effects (SOC) in accordance with the present disclosure.

FIGS. 7A and 7B illustrate exemplary embodiments of the crystal orbital Hamilton population (COHP) bonding analysis of KBaTeBiO₆ for Bi—O (FIG. 7A) and Te—O (FIG. 7B) bonds in accordance with the present disclosure. Positive values indicate bonding character while negative values indicate antibonding character.

FIG. 8 is an exemplary embodiment of the TGA profile of a dried precursor material in accordance with the present disclosure.

FIG. 9 is the Rietveld refinement of the experimental XRD data and the quality of the fit. The expected lattice parameters are calculated from DFT.

FIG. 10 is an exemplary embodiment of the overlaid XRD patterns of freshly prepared KBaTeBiO₆ and after storing under ambient conditions for 380 days in accordance with the present disclosure.

FIG. 11 is an exemplary embodiment of the EDS mapping of KBaTeBiO₆ powder in accordance with the present disclosure.

FIG. 12 is a table listing the space group symmetry and corresponding octahedral tilt patterns for the AA′BB′O₆ and A₂BB′O₆ systems.

FIGS. 13A, 13B, 13C, and 13D show polyhedral representation of an inorganic ABX₃ perovskite (FIG. 13A): A (green) cation, B (blue) cation and X (red) anion in accordance with the present disclosure. FIGS. 13B and 13C illustrate the ionic radius definitions for A, B and X. FIG. 13D illustrates the dependence of perovskite structure on the tolerance factor.

FIGS. 14A, 14B, and 14C illustrate the variation in formation enthalpy (FIG. 14A) scaled HSE+SOC band gap (FIG. 14B) for the AA′TeBiO6 family of compounds, with their relative scales shown at the bottom, in accordance with the present disclosure. The y and x-axis represent the A and A′ cations respectively. FIG. 14C is the band structure of RbBaTeBiO₆ calculated using HSE+SOC.

Unless otherwise indicated, the drawings provided herein are meant to illustrate features of embodiments of the disclosure or results of representative experiments illustrating some aspects of the subject matter disclosed herein. These features and/or results are believed to be applicable in a wide variety of systems comprising one or more embodiments of the disclosure. As such, the drawings are not meant to include all additional features known by those of ordinary skill in the art to be required for the practice of the embodiments, nor are they intended to be limiting as to possible uses of the methods disclosed herein.

### DETAILED DESCRIPTION OF THE DISCLOSURE

The present disclosure is directed to double perovskite oxide semiconductors. In particular, the present disclosure is directed to lead-free double perovskite oxides that provide excellent stability and are used, for example, as photovoltaic materials.

In the following specification and the claims, reference will be made to a number of terms, which shall be defined to have the following meanings. The singular forms “a,” “an,” and “the” include plural references unless the context clearly dictates otherwise. The terms “comprising,” “including,” and “having” are intended to be inclusive and mean that there may be additional elements other than the listed elements. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

As used herein, “band gap” refers to the energy gap (measured in eV) between the valence band and the conduction band in a solid. Insulators have a large band gap while conductors have zero band gap. Semiconductors are in between. Although there are no specific numerical cutoffs between semiconductors and insulators, most semiconductors used in solar or photovoltaic applications have a band gap ranging from 1.0 to 2.0 eV.

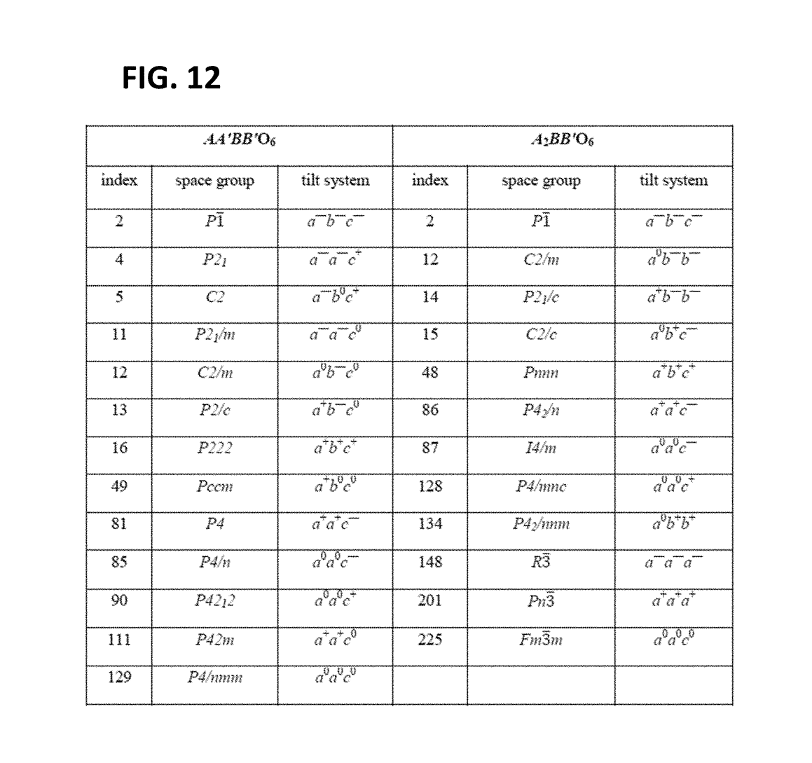

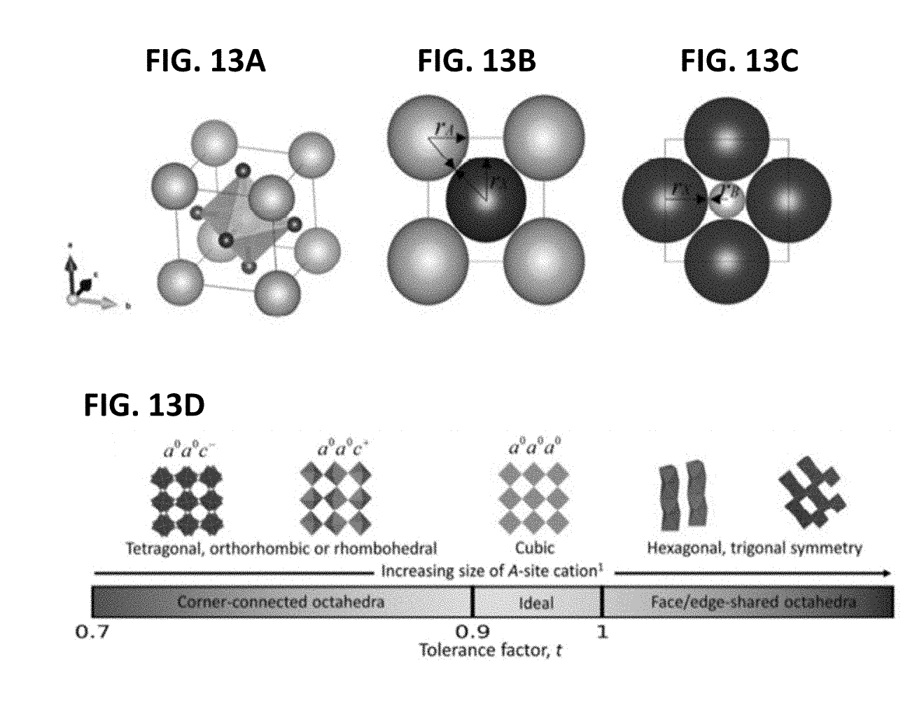

As used herein, “perovskite” refers to a class of compounds having a similar crystal structure as CaTiO₃. The general formula of an ideal perovskite is ABX₃ with A and B being many different metal cations and X being either a halide or oxygen. It consists of B-site cations under an octahedral coordination of X anions. The BX₆ octahedra are corner-connected. The A-site cation, which is usually larger in size, occupies the cuboctahedral sites created by the corner connected BX₆ octahedra. Only a few perovskites adopt this ideal structure whereas most of the perovskites undergo distortions, which result in a lowering of the symmetry. The most common distortions involve cooperative tilting of the octahedra around a crystallographic-direction (see FIG. 12). Due to the octahedral tilts, the perovskite framework accommodates a large combination of cations and anions from the Periodic Table (see FIGS. 13A to 13D).

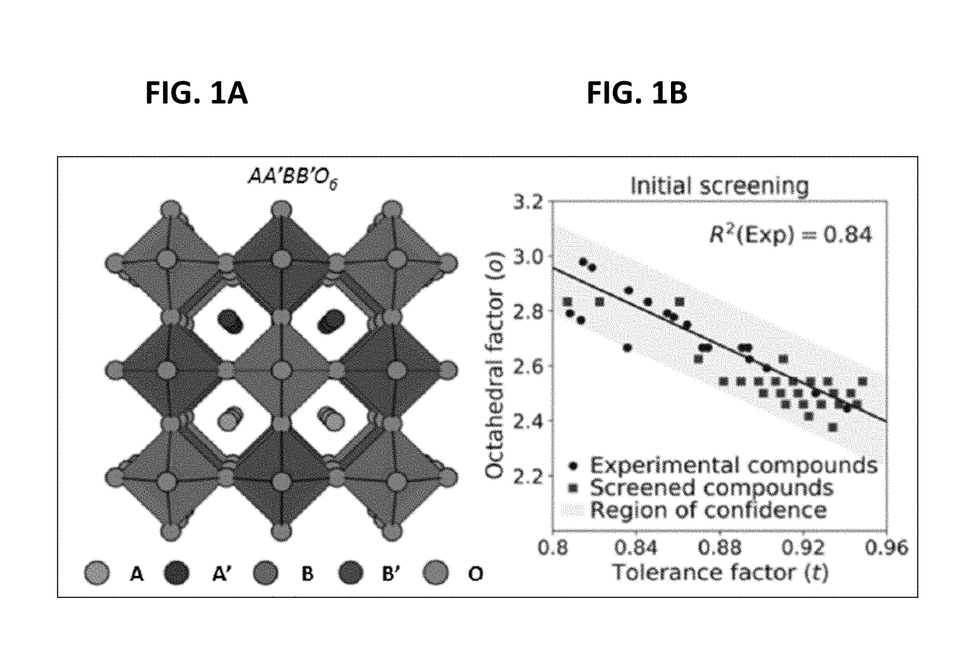

As used herein, “double perovskite” refers to a class of compounds having a similar crystal structure as a perovskite except the general formula is AA′BB′X₆ where A and A′ are the same or are different metal cations while B and B′ are different metal cations. In some embodiments, X is either a halide or oxygen. An ideal double perovskite with a general formula of AA′BB′X₆ is an extension of the cubic ABX₃ perovskite structure, where A and A′ represent inequivalent A-site cations while B and B′ represent inequivalent B-site cations (see FIG. 1A). For a fixed X-site anion, the perovskite structure accommodates a varied range of cations both at A and B-sites. In many embodiments disclosed herein, B′ is bismuth. In some aspects disclosed herein, the double perovskites do not include lead as one of the metal cations. Note that “B” in this application does not refer to the element boron. If the element boron is referenced herein, it will be clearly identified by name. In some embodiments, RbMgTeBiO₆, NaCaTeBiO₆ and KCaTeBiO₆ are excluded from the composition of formula AA′BB′X₆. In accordance with the present disclosure, it is understood by those having ordinary skill in the art that the identification of a double perovskite as A′A″B′B″ is interchangeable with a double perovskite identified as AA′BB′.

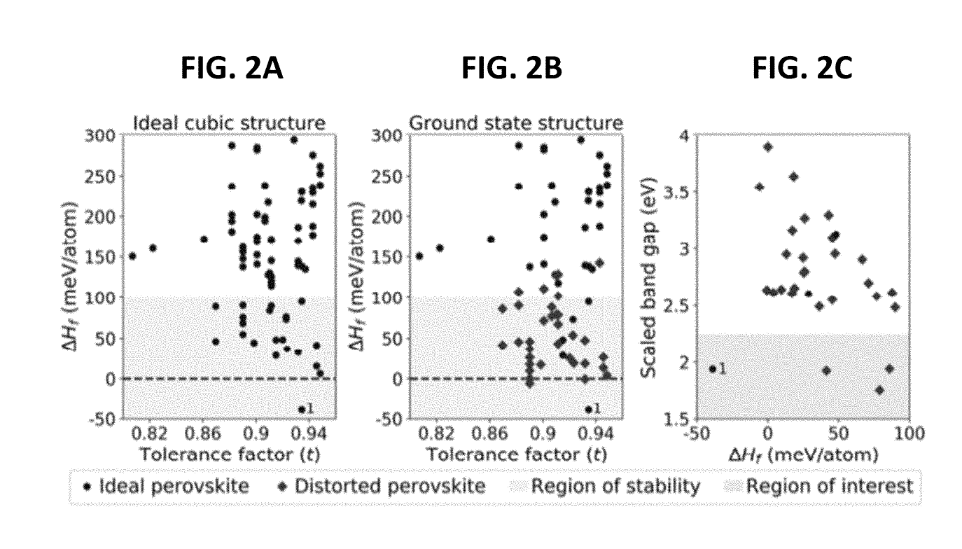

In order to determine which lead-free double perovskites would be suitable for use in photovoltaic applications, a computational approach was first explored. Any potential candidate for photovoltaic applications, in addition to being formable, should also exhibit an optimal band gap (˜1.6 eV) and electronic structure for maximum possible absorption of the solar spectrum. The Bi³⁺ cation was initially selected as a replacement for lead because it is isoelectric with the Pb²⁺ cation. Generalized Gradient Approximation GGA, such as the Perdew-Burke-Ernzerhof (PBE) functional, are known to underestimate the band gap. To predict experimental band gaps more accurately, the hybrid Heyd-Scucesria-Ernzerhof (HSE06) functional was used. Spin-orbit coupling effects (SOC) were also included, as they are expected to be significant due to the presence of the heavy Bi³⁺ cation. Because HSE06+SOC calculations are computationally expensive, they were used to calculate the band gap of 25% of the stable compounds. For the remaining stable compounds, they were linearly scaled to the PBE band gaps (E_{g}(PBE)) using E_{g}(HSE+SOC)=0.87 Eg(PBE)+0.84, to obtain scaled HSE+SOC band gaps (E_{g}(HSE+SOC)). Such empirical linear scaling has previously been shown to have a reasonable accuracy for predicting calculated GW band gaps. FIG. 2C shows the scaled band gap of compounds that are below a predetermined stability criteria (ΔH_{f}<100 meV/atom). Two compounds KBaTeBiO₆ and SrBaVBiO₆, having a calculated E_{g} of 1.94 and scaled E_{g} of 2.18 eV were further studied. Thus, in some embodiments, B or B′ is Bi³⁺.

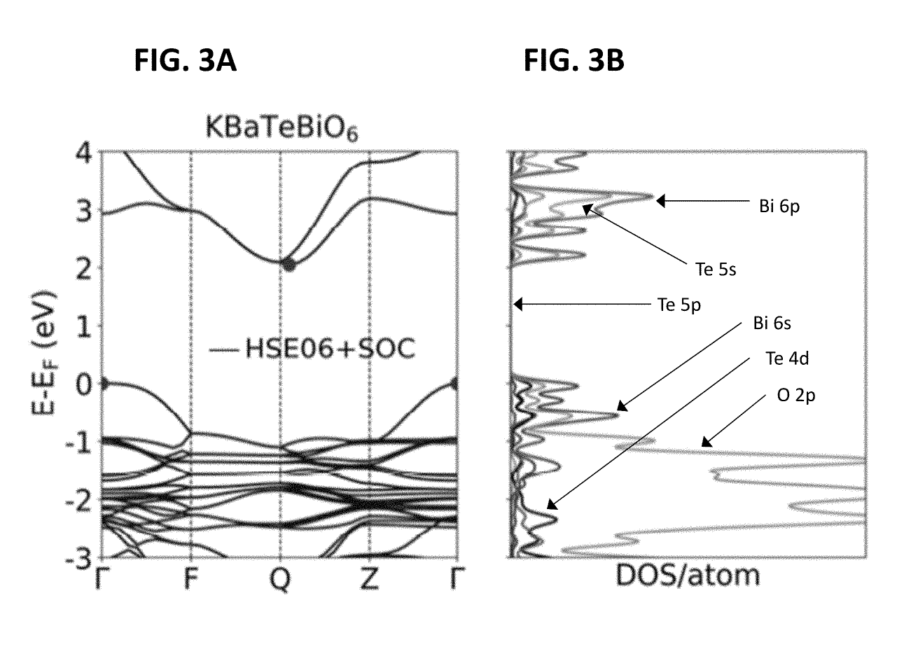

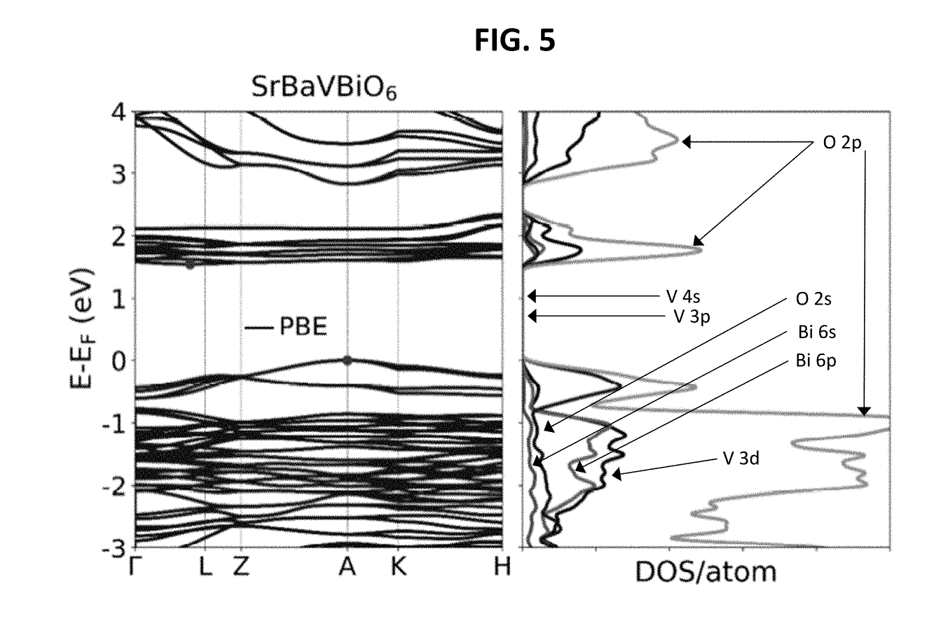

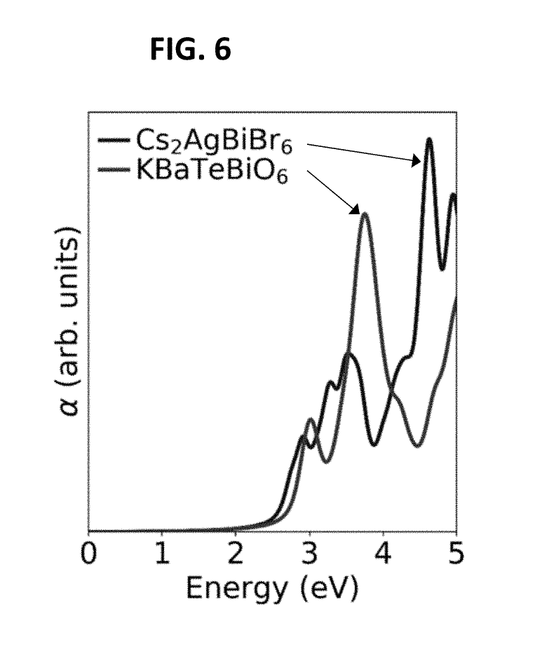

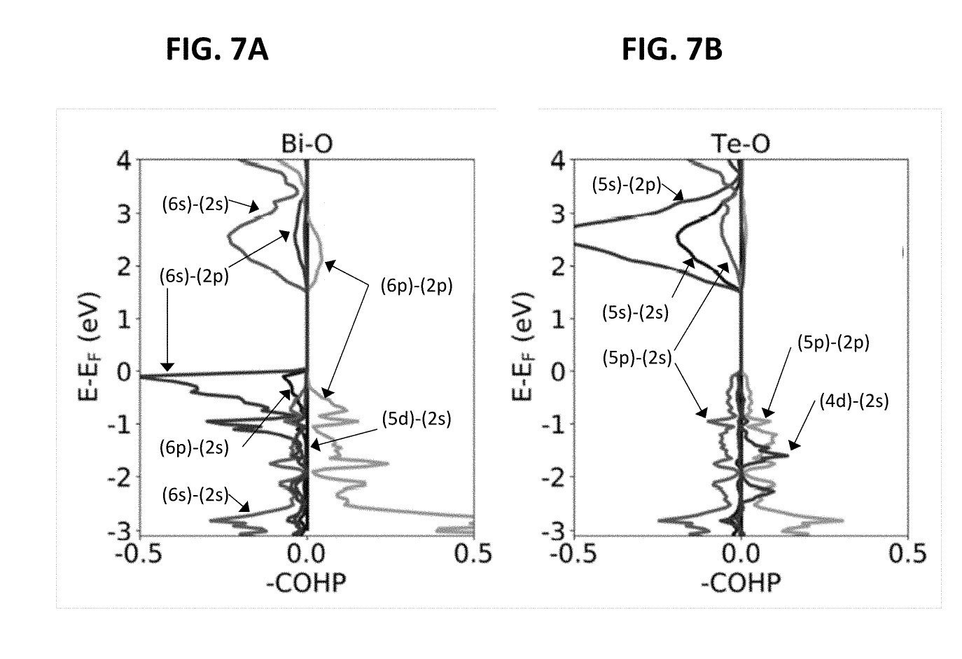

In addition to an optimal band gap, highly dispersed conduction and valence bands are desirable for faster transport of electrons and holes. Based on the calculated band structure, SrBaVBiO₆ exhibits flat bands, as shown in FIG. 5. KBaTeBiO₆ exhibits widely dispersed bands, as shown in the band structure plot calculated using HSE+SOC (FIG. 3A). The atom-projected density of states (DOS) is shown in FIG. 3B. KBaTeBiO₆ has a predicted indirect band gap of 1.94 eV from Γ(0, 0, 0) to (0, 0.45, 0.5), which is similar to the calculated indirect band gap of 2.06 eV (2.62 eV) for Cs₂AgBiBr₆ (Cs₂AgBiCl₆). The theoretical direct band gap of KBaTeBiO₆ is 2.83 eV and occurs at Γ, whereas the direct band gap of Cs₂AgBiBr₆ (Cs₂AgBiCl₆) is 2.45 eV (3 eV). The effective mass of holes in KBaTeBiO₆ is 0.25 mₑ (mₑ is the rest mass of an electron) along Γ−Z, which is heavier than that for Cs₂AgBiBr₆ (0.14 mₑ) and Cs₂AgBiC1₆ (0.15 mₑ). Whereas the effective mass of electrons for KBaTeBiO₆ is 0.28 mₑ along conduction band minimum (0, 0.45, 0.5) to Q (0, 0.5, 0.5), which is lighter than that of Cs₂AgBiBr₆ (0.37 me) and Cs₂AgBiC1₆ (0.53 mₑ). Overall, the low effective masses of electrons and holes for KBaTeBiO₆ points towards favorable carrier transport. Moreover, a comparison of the calculated absorption spectra of KBaTeBiO₆ and Cs₂AgBiBr₆ (as shown in FIG. 6) shows promising absorbance for the former. In KBaTeBiO₆, the valence band is predominantly made up of O-2 p, Bi-6 s states with a small contribution of Te-4 d states, as shown in the DOS plot in FIG. 3B. The contribution of the d-states at the valence band edge is responsible for the indirect nature of the band gap for KBaTeBiO₆. This is similar to the effect of Ag-4 d states in case of Cs₂AgBiBr₆ and Cs₂AgBiC1₆. The conduction band is largely made up of Bi-6 p and Te-5 s states with a small contribution from O-2 p states as shown in FIGS. 7A and 7B.

Thus, in some embodiments, the double perovskite has a formula of KBaTeBiO₆. In some embodiments, the double perovskite is not RbMgTeBiO₆, NaCaTeBiO₆ or KCaTeBiO₆. That is, the double perovskite has a formula different than RbMgTeBiO₆, NaCaTeBiO₆ or KCaTeBiO₆.

Due to their chemical complexity, double perovskites are prone to the formation of various kinds of defects. These include antisite disorder, oxygen and cation vacancies, non-stoichiometry anti-phase boundaries, regions with different octahedral tilt pattern, grain boundaries and phase segregation. Each of these defects can affect the electronic structure. For instance, the degree of chemical disorder (by the formation of antisites) can lead to either a direct or indirect band gap. Cooperative octahedral tilts of the BX₆ units are known to change the bandgap of APbI₃ from (1.3−2) eV. Oxygen vacancies in perovskites are known to introduce electrons to fill hole-states or lead to n-type doping. Grain boundaries in CH₃NH₃PbI₃ have been shown to have metallic behavior as a result of chemical inhomogeneity and help in carrier separation.

In order to characterize such defects and understand their effect on the electronic structure, a combination of aberration-corrected STEM imaging, monochromated EELS and DFT calculations is used. Aberration-corrected STEM imaging and spectrometry allows direct and simultaneous access to the geometry and electronic structure at the atomic scale. High-angle annular dark field imaging (HAADF) or Z-contrast imaging, which is sensitive to the heavier cations to image their local distribution and measure antisite disorder, is used. The changes in octahedral tilts are monitored by using simultaneously acquired annular bright field (ABF) images, which are sensitive to the lighter elements. The presence of extended defects, such as, antiphase boundaries, grain boundaries, and strain due to local clustering or phase segregation are mapped using medium angle ADF (MAADF) imaging. The coordinates of the atomic column are extracted from these images to determine local crystal structure including effects such as sub-lattice expansion that are caused by ordered oxygen vacancies, changes or gradients in tilt patterns, and local polar distortions.

In conjunction with imaging, monochromated EELS is performed to understand the local composition and electronic structure. Core-loss EELS is performed for elemental mapping to determine changes in composition and the oxidation states of transition metal atoms, both in the bulk and across extended defects such as grain boundaries. This allows for monitoring possible segregation of impurities at the grain boundaries. Furthermore, it is possible to obtain low-loss EELS and measure changes in dielectric constant, band gaps and even defect states within the band gap. Combined together, the STEM-EELS experiments provide insights into defects in these heavy-metal perovskites and their effect on the electronic properties.

In order to relate the microstructural information from STEM-EELS characterization with the macroscopic properties, such as the activation barrier for transport, the type of conductivity (n-type or p-type), carrier concentration and lifetimes and the defect-tolerance of the material, DFT calculations are used. The formation energy of the different point defects (vacancies and antisites) is calculated under various chemical potentials (that can be related to the growth conditions) to determine the defect concentration and their effect on the concentration of the carriers. The thermodynamic transition levels are obtained by varying the electron potential to identify shallow and deep level defects and compare them with DLTS and Hall measurements. Likewise, the optical transition levels are compared with results from low-loss EELS and optical spectroscopy measurements. The STEM results are particularly useful to build realistic models of the dominant extended defects, such as grain boundaries, antiphase boundaries and chemical or phase segregation, for subsequent DFT calculations to understand their effect on the electronic properties. Together the combination of various characterization including STEM and DFT permits an understanding of the defect-tolerant nature of these semiconductors.

DFT calculations are used to study the stability of the dominant defects under various growth conditions and predict those conditions that lead to reduction in defect concentration. The formation energy of the defects is calculated by varying the chemical potential of the elements. For instance, in the case of BiI₃, a higher carrier concentration was achieved for films grown under Bi-rich conditions. This strategy has been applied to achieve record photovoltaic efficiency of CH₃NH₃PbI₃-based solar cells by identifying and subsequently growing CH₃NH₃PbI₃ under I-rich conditions to reduce the concentration of defects that acted as recombination centers. Similarly, for secondary phases, DFT calculations are used to guide growth and processing conditions, where they are avoided. For those extended defects, such as grain boundaries, dislocations, etc. that are found to be electrically active and can act as recombination centers, DFT calculations are used to identify suitable elements that can passivate the dangling bonds at the extended defects and make them inert. DFT calculations are also used to identify suitable dopants that can selectively improve the conductivity of holes and electrons in the Bi-based perovskites.

In some embodiments, there is a high probability of the presence of defects in these double perovskites due to their chemical complexity. Gas phase, aerosol synthesis routes allow for good control of defects in the nanostructured materials. The number of defects depends on various synthesis parameters, such as, but not limited to, temperature gradients, dopants and multi-components, and reaction rates of the various precursors. In some embodiments, there are two methods to achieve the reduction in defects: a) develop a relationship of synthesis parameters to defect densities, and then alter the conditions to change the density of defects; and b) post-annealing under controlled conditions to alter the defect densities. In one non-limiting example, the grain boundaries were controlled and grain size of CH₃NH₃PbI₃ films deposited using electrospray technique by healing them during postdeposition annealing in ambient air. In some embodiments, for better control over the structure and chemical composition, thin-film synthesis techniques are used, including pulsed laser deposition and molecular beam epitaxy.

As noted earlier, oxygen vacancies in perovskites are known to introduce electrons to fill hole-states or lead to n-type doping. In some embodiments, various doping strategies are used to improve the concentration of electrons and holes and to facilitate their separation to contacts. The doping strategies include, but are not limited to, changing the concentration of oxygen vacancies, as well as substituting some or all of the oxygen with either nitrogen or fluorine. In some embodiments, intrinsic doping, extrinsic doping, or both are used in accordance with the present disclosure. In some embodiments, oxygen vacancy-based intrinsic doping is used.

In some embodiments, disclosed herein is a lead-free double perovskite having a formula of AA′BB′Xₙ, wherein A and A′ are the same or are different and is selected from the group consisting of alkali metals, alkaline earth metals, actinides, transition metals, post-transition metals and metalloids; B and B′ are different and selected from the group consisting of alkali metals, alkaline earth metals, actinides, transition metals, post-transition metals and metalloids; X is selected from the group consisting of fluorine, chlorine, bromine, iodine, oxygen and nitrogen; and n is a real number from 2 to 6. In some embodiments, n=6. In some embodiments, the lead-free double perovskite has the formula AA′BB′Oₙ, wherein A and A′ are the same or are different and is selected from the group consisting of alkali metals, alkaline earth metals, actinides, transition metals, post-transition metals and metalloids; B and B′ are different and selected from the group consisting of alkali metals, alkaline earth metals, actinides, transition metals, post-transition metals and metalloids; and n is a real number from 2 to 6.

In yet another embodiment, disclosed herein is a lead-free double perovskite having a formula AA′BB′Xₙ wherein A and A′ are the same or are different and is selected from the group consisting of alkali metals, alkaline earth metals, actinides, transition metals, post-transition metals and metalloids; B and B′ are different and selected from the group consisting of alkali metals, alkaline earth metals, actinides, transition metals, post-transition metals and metalloids; X is selected from the group consisting of fluorine, chlorine, bromine, iodine, oxygen and nitrogen; n is a real number from 2 to 6, and the stoichiometric mole ratio of A to A′ to B to B′ to X is from 1 to (0.5-3.0) to (0.5 to 3.0) to (0.5 to 3.0) to (2.0 to 6.0). In some aspects, the stoichiometric ratio of A to A′ to B to B′ to X is from 1 to (0.5-2.0) to (0.5 to 2.0) to (0.5 to 2.0) to (2.0 to 6.0). In some aspects, the stoichiometric ratio of A to A′, B, B′ and/or X is 1 to about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, about 2.0, about 2.1, about 2.2, about 2.3, about 2.4, about 2.5, about 2.6, about 2.7, about 2.8, about 2.9, or about 3.0; and each ratio is determined independently from each of the others. In some embodiments, at least one of A, A′ and B are equal to 0. As used in this context, “about” means±0.05. In some embodiments, the sum of the oxidation states of A, A′ and B is 9.

In some embodiments of the present disclosure, disclosed herein is a lead-free double perovskite having a formula AₓA′₂₋ₓB_{y}Bi_{2-y}Xₙ wherein 2≥x, y≥0 and n is a real number from 5≥n≥6, wherein A and A′ are the same or are different and is selected from the group consisting of alkali metals, alkaline earth metals, actinides, transition metals, post-transition metals and metalloids; B is selected from the group consisting of alkali metals, alkaline earth metals, actinides, transition metals, post-transition metals and metalloids; X is selected from the group consisting of oxygen and nitrogen; and each ratio is determined independently from each of the others. In some embodiments, at least one of A, A′ and B are equal to 0.

In some embodiments, A and A′ are the same. In some embodiments, A and A′ are different. In some embodiments, at least one of A and A′ is selected from the group consisting of sodium, potassium, rubidium, cesium, magnesium, calcium, strontium, barium and radium. In some exemplary embodiments, at least one of A and A′ is potassium. In some exemplary embodiments, at least one of A and A′ is barium.

In some embodiments, one or both of B and B′ are post-transition metals or metalloids selected from the group consisting of aluminum, gallium, indium, tin, thallium, bismuth, polonium, boron, silicon, germanium, arsenic, antimony, tellurium and astatine. In some exemplary embodiments, one of B or B′ is bismuth. In some exemplary embodiments, one of B or B′ is tellurium.

In some embodiments, X is selected from the group consisting of fluorine, chlorine, bromine, iodine, oxygen and nitrogen. In some embodiments, X is a halide. In some embodiments, X is oxygen. In some embodiments, X is nitrogen. In some embodiments, “n” is a real number from 2 to 6. For example, in some embodiments n is 2, 3, 4, 5, or 6.

In some embodiments, the metal cations in the lead-free double perovskite are any stable valence for the specific metal cation. In one non-limiting example, Fe(II), Fe(III) and Fe(IV) are known stable ions for iron. As such, all three are encompassed herein. In yet another non-limiting example, Bi(I), Bi(III) and Bi(V) are known stable ions for bismuth and encompassed herein. In all cases the lead-free double perovskite will be a neutral molecule with a chemically viable structure. The valence of each individual metal cation will be selected independently of the other up to the limits of stability for the individual cation and the overall lead-free double perovskite. In another non-limiting example, if B is the Bi³⁺ cation and X is oxygen with “n” equal to 6, then the sum of the valence charges of the other metal cations will be 9. In yet another non-limiting example, if B is the Bi³⁺ cation and X is a halide with “n” equal to 6, then the sum of the valence charges of the other metal cations will be 3.

In some embodiments, the lead-free double perovskite has a band gap of from about 1.0 to 3.0 eV. In some embodiments, the band gap is from about 1.1 to 2.5 eV, about 1.2 to 2.0 eV, or about 1.3 to 2.0 eV. In yet another embodiment, the band gap is about 1.0 eV, about 1.1 eV, about 1.2 eV, about 1.3 eV, about 1.4 eV, about 1.5 eV, about 1.6 eV, about 1.7 eV, about 1.8 eV, about 1.9 eV, about 2.0 eV, about 2.1 eV, about 2.2 eV, about 2.3 eV, about 2.4 eV, or about 2.5 eV. As used in this context, “about” means±0.1 eV.

In yet another embodiment, the lead-free double perovskite has a ΔH_{f} that is at or below 100 meV/atom for the ideal cubic structure. In yet another embodiment, the lead-free double perovskite has a ΔH_{f} that is at or below 100 meV/atom for the ground state structure.

The lead-free double perovskites as disclosed herein are useful in many different applications. As a non-limiting example, the lead-free double perovskites disclosed herein are useful in both semiconductor and photovoltaic applications, including solar cells.

### EXAMPLES

Computational Details:

DFT calculations were performed using the Vienna Ab-initio Simulation Package (VASP) using the projector-augmented-wave (PAW) method. The generalized gradient approximation (GGA) method as implemented in the Perdew-Burke-Ernzerhof (PBE) functional for crystal and electronic structure optimization was used. The enforcement of layered and rock-salt ordering at the A and B-site, respectively, lead to a 20-atom supercell having two formula units (f.u.) of the double perovskite. This supercell is a √2×√2×2 transformation of a typical 5-atom ABX₃ perovskite primitive unit cell. The initial lattice parameters for geometric optimization (a, b and c) were approximated from the Slater's atomic radii such that a=b=√2(r_{B}+rₓ) and c=4(r_{B}+rₓ). A plane-wave basis set with a cutoff of 400 eV for the coarse and fine relaxation steps with 520 eV for the final static total energy calculation step was used. The Brillouin zone was sampled using a Gamma-centered Monkhorst-Pack k-points mesh while keeping the kpoints per reciprocal atom (KPPRA) ˜8000 for the fine relaxation and the single-step static calculation. The fine relaxation and the static calculation were carried out in accordance with pseudopotentials and other DFT settings employed by OQMD. For the HSE06 calculations, the fraction of Hartree-Fock exchange (a) was fixed at 0.25, and an inverse screening length of 0.207 Å⁻¹ was used.

Formation Enthalpy Determination

The method for the determination of the most probable reaction pathway is based on an evaluation of the convex hull in a multi-dimensional phase space and subsequent minimization of the free energy of the multicomponent reactants, assuming a reversible chemical reaction. For any hypothetical chemistry, the multi-component reactants and their coefficients are generated using the grand canonical linear programming (GCLP) approach implemented within OQMD. The formation enthalpy and thermodynamic stability of a hypothetical double perovskite can be then evaluated from the DFT total energy of the double perovskite and the combined total energy of the reactants. For one non-limiting example, Equation 1 shows the reaction pathway for KBaTeBiO₆, as evaluated by OQMD. The formation enthalpy of this compound (ΔH_{f} (KBaTeBiO₆)) is calculated using Equation 2, where E(KBaTeBiO₆) is the DFT total energy/f.u. of KBaTeBiO₆, while E(K₂TeO₃), E(Bi₂O₃), E(KBiO₃) and E(Ba₃Te₂O₉) are DFT total energies/f.u. of the reactants obtained either from OQMD or calculated. This methodology for calculating formation enthalpy using multicomponent reactants is more accurate than using elemental energies as the reference point.

1/3K₂TeO₃+1/3Bi₂O₃+1/3KBiO₃+1/3Ba₃Te₂O₉→KBaTeBiO₆ (Equation 1)

ΔH_{f}(KBaTeBiO₆)=E(KBaTeBiO₆)−[E(K₂TeO₃)−E(Bi₂O₃)−E(KBiO₃) −E(Ba₃Te₂O₉)]/3 (Equation 2)

The perovskite framework accommodates a variety of cations with different oxidation states and ionic radii for both type of cations for a fixed choice of anion at the X-site. This is achieved through a cooperative tilting in the BX₆ octahedra. These tilts allow for the optimization of the coordination environment of the A-site cations, where the extent and type of tilting are dependent on the relative size of the cubooctahedral cavities and the size of the A-site cation. The octahedral tilts and their effects on the space group symmetry have been studied extensively for the double perovskite structure. These results are summarized in the Table in FIG. 12.

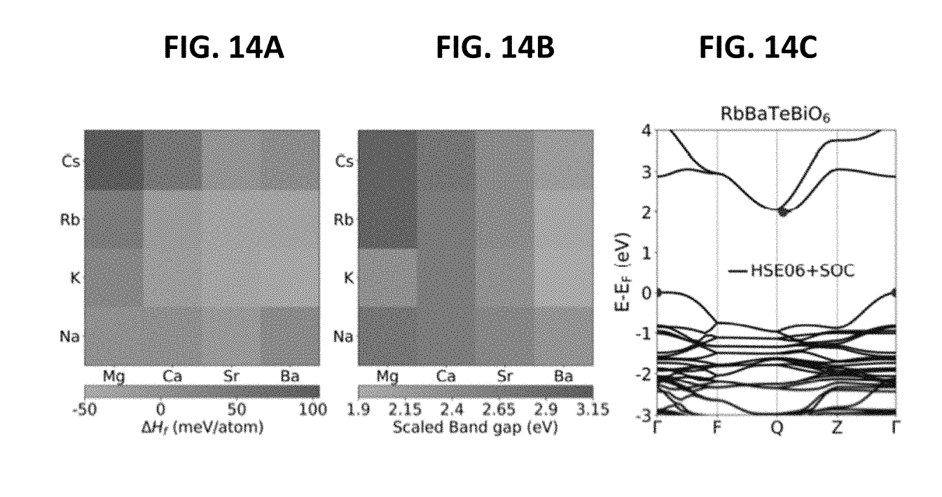

Encouraged by the band structure of KBaTeBiO₆, additional cation substitution strategies within the AA′TeBiO₆ framework were conducted to continue searching for promising semiconductors. Alkali metals (Na, K, Rb and Cs) at the A-site and alkaline earth metals (Mg, Ca, Sr and Ba) at the A′-site were examined. Due to the extremely small size of the Li⁺ and Be⁺ cations for the cubooctahedral cavities, they were excluded as possible A-site candidates. From evaluation of the formation enthalpies, the AA′TeBiO₆ family of double perovskite oxides show exceptional thermodynamic stability (FIG. 14A). For the ideal double perovskite structure, 11 of the total 16 compounds have ΔH_{f}<100 meV/atom and 5 of those structures have a negative formation enthalpy. After accounting for octahedral tilts, all the compounds, except one, lie in the region of stability (ΔH_{f}<100 meV/atom). The only exception being CsMgTeBiO₆ with ΔH_{f}=104 meV/atom. This exception is due to the size of the Mg²⁺ cation, which is too small for the cubo-octahedral cavities. Furthermore, 14 of the total 16 compounds have a ground state with ΔH_{f}<50 meV/atom, where 8 of those compounds have a ground state with negative formation enthalpy.

KBaTeBiO₆, RbBaTeBiO₆ and CsBaTeBiO₆ exhibit an ideal perovskite structure in their ground state, without octahedral tilts, whereas other 13 compounds have tilted structures as their ground state. There is an appreciable decrease in the calculated ΔH_{f} on introducing octahedral tilts for these 13 compounds. The average decrease in ΔH_{f} on introducing octahedral tilts is 76 meV/atom with a standard deviation of 96 meV/atom. The decrease in ΔH_{f} is much larger for compounds with smaller A-site cations than those with a larger A-site cation. For compounds with A′=Mg, which is the smallest A′-site cation, the ground state tilted structure is on average 218 meV/atom lower in energy than the ideal perovskite structure. This lowering of energy on including octahedral tilts is highest for NaMgTeBiO₆, which has a P1 phase ground state. The P1 phase of NaMgTeBiO₆, which has the smallest combination of A and A′-site cations, is 324 meV/atom lower in energy than its ideal perovskite polymorph. To accommodate two small A-site cations, Na⁺ and Mg²⁺, both sets of TeO₆ and BiO₆ octahedraundergo cooperative tilting in all three crystallographic directions to optimize the coordination environment of the A-site cations. Whereas, for A′=Ba, which is the largest A′-site cation, the coordination environment of the A-site is already optimized in the ideal perovskite structure. As a result, 3 of the total 4 compounds with A′=Ba, have the ideal perovskite structure as their ground state. The lowering of the energy is directly related to the degree of tilting in the ground state structure with respect to the ideal double perovskite structure. The compounds with their ideal double perovskite structure farther away from the bottom of the convex hull (or higher ΔH_{f}) show a higher degree of octahedral tilting in their ground state structure. For e.g. the ground state for NaMgTeBiO₆ is P1, which corresponds to the tilting of the octahedra in all three crystallographic directions (a⁻b⁻c⁻) to accommodate the small A-site cations.

Although A-site cations don't contribute directly to the electronic structure of the double perovskite, they heavily influence the hybridization of the B-site cation states and 0 states. Depending on the size of the A-site cation, the ground state phase of a double perovskite undergoes octahedral tilting. As a result of this octahedral tilting the B—O—B′ bond angle changes, which impacts the coupling of the B-site cation states with O states. For the AA′TeBiO₆ compounds, the scaled band gap varies from 1.94 eV to 2.36 eV for the ideal double perovskite structure. Whereas, for the ground state structure, after including octahedral tilts, the scaled band gap varies from 1.94 eV to 3.1 eV, as shown in FIG. 14B. This increase in band gap variation for the tilted AA′TeBiO₆ structures as compared to the ideal AA′TeBiO₆ structures is a result of the varying degree of octahedral tilting owing to the size of the A and A′-site cations.

FIG. 14C illustrates the band structure for another promising compound, RbBaTeBiO₆, with undistorted ground state belonging to a space group symmetry of P4/mm. Similar to KBaTeBiO₆, RbBaTeBiO₆ has an indirect band gap of 1.99 eV from F (0, 0, 0) to (0, 0.45, 0.5), whereas the direct band gap is 2.86 eV, which occurs at Γ. The effective mass of holes along Γ-Z for RbBaTeBiO₆ is 0.29 mₑ, while that of electrons along conduction band minimum (0, 0.45, 0.5) to Q (0, 0.5, 0.5) is 0.22 mₑ. These effective masses are similar to that of KBaTeBiO₆ and bismuth-halide double perovskites.

Electronic Structure of SrBaVBiO₆

Several of the screened double perovskite oxides exhibit wide band gaps with flat electronic bands. As shown in FIG. 5, SrBaVBiO₆ exhibits flat electronic bands, with an indirect PBE band gap of 1.61 eV and scaled HSE+SOC (approximated as described in main text) band gap of 2.18 eV. The electronic band characteristics are expected to be similar for PBE and HSE+SOC calculations. These flat bands are also observed for other compounds, such as RbSrNbBiO₆ and KSrMoBiO₆, which have a transition metal cation at the B-site. The reason for the indirect band gap and flat bands in case of double perovskite oxides is understood by analyzing the DOS plot (FIG. 5). In SrBaVBiO₆, the valence band is predominantly made up of O-2 p, O-2 s, V-3 p with a small contribution from Bi-6 p and V-3 d states respectively. The contribution of the d states at the valence band edge is responsible for the indirect nature of the band gap for SrBaVBiO₆. This is similar to the effect of Ag-4d states in case of Cs₂AgBiBr₆ and Cs₂AgBiC1₆. The conduction band edge is predominantly made up of O-2 p and V-3 d. As compared to KBaTeBiO₆ (FIG. 3B), the contribution of the V-3 d states contribute significantly more towards band edges than the Te-4 d states. This increased contribution of the V-3 d states in SrBaVBiO₆ leads to the flattening of the electronic bands at both the conduction and valence band edges.

Calculated Absorption Spectra for KBaTeBiO₆

The absorption spectra of KBaTeBiO₆, calculated using HSE06+SOC, is provided in FIG. 6. It is clearly seen that there is a small absorption onset around the indirect band gap followed by a large photon absorption onset that occurs at a larger value than the indirect band gap and is almost equal to the direct band gap value. The presence of an indirect band gap implies the use of a thicker layer of absorber material for large photoconversion efficiency. The calculated absorption spectrum of Cs₂AgBiBr₆ in FIG. 6 shows similar characteristics to that of KBaTeBiO₆. The comparison of the absorption spectra of KBaTeBiO₆ and Cs₂AgBiBr₆ further illustrates the expected similarity in the photovoltaic performance of both materials. For calculating the absorption spectra, the total number of bands was tripled with respect to the DFT default to accommodate sufficient empty conduction bands.

Chemical Bonding Analysis for KBaTeBiO₆

As shown in FIGS. 7A and 7B, the valence band edge is predominantly composed of (Bi-6 s)-(O-2 p) antibonding interactions while the conduction band edge is composed of (Bi-6 p)-(O-2 s), (Te-5 s)-(O-2 p) and (Te-5 s)-(O-2 s) antibonding interactions. The contribution of O-2 p states is significantly lower in the COHP plot than in the DOS plot near the valence band edge due to a large amount of non-bonding O-2 p states. The chemical bonding analysis was performed using plane wave based crystal orbital Hamilton population (COHP) analysis.

A simple two-parameter linear regression model—built on only two structural parameters—accurately describes the formability of all previously known Bi based double perovskite oxides (reported in ICSD) with an R-squared value of 0.84, as shown in FIG. 1B. The farthest lying experimental data point (blue) from the fitted line to define a rectangular area used as the region of confidence. A total of 144 hypothetical AA′B′BiO₆ double perovskites lie within this region of confidence as shown using red data points in FIG. 1B for subsequent geometry optimization. Many of the screened compounds have the same set of tolerance and octahedral factors and are overlying in FIG. 1B.

Geometry optimization was carried out in a two-step procedure involving a coarse relaxation followed by a fine relaxation. For the coarse relaxation, all hypothetical compounds were considered to be ideal double perovskites without any octahedral tilts. In some embodiments, an ideal double perovskite is classified into one of two space group symmetries: Fm-3m when A=A′ and P4/nmm when A A′. As shown in FIG. 1A, a layered ordering for the A-site cations (A′ and A) and rock-salt ordering for the B-site cations (B′ and B) was imposed which is most prevalent in ordered double perovskites. The same DFT settings as those used in the Open Quantum Materials Database (OQMD) enable the calculation of formation enthalpy (ΔH_{f}) of the hypothetical double perovskites with respect to the most stable reactants, which are elements or compounds.

In principle, a negative formation enthalpy suggests that the compound is stable and can be synthesized. However, it has been previously shown that metastable compounds are fairly common as they find about the 90^{th} percentile of the experimental binary oxides lie within 94 meV/atom above the ground state polymorph. Thus, a similar criterion was set to include metastable AA′BBiO₆ compounds having ΔH_{f}<100 meV/atom that can be expected to be formable. FIG. 2a shows the variation of formation enthalpy with the tolerance factor for all of the screened ideal double perovskites. Within the ideal double perovskite structure, as shown in FIG. 2A, only one compound has a negative formation enthalpy: KBaTeBiO₆ (ΔH_{f}=−39 meV/atom) and 21 compounds lie inside the region of stability (ΔH_{f}<100 meV/atom).

Cooperative-tilting of the BX₆ octahedra further stabilizes the perovskite structure by lowering the crystal symmetry. The octahedral tilts and their effect on the space group symmetry were studied for the double perovskite structure and are summarized in the table in FIG. 12. For those compounds having ΔH_{f}<200 meV/atom, a geometry optimization was performed starting with all possible octahedral tilt patterns. For most compounds, the ground state has an octahedral tilt. As shown in FIG. 2B, 36 compounds are now in the region of stability (ΔH_{f}<100 meV/atom) with 5 compounds having a negative formation enthalpy. Of these, there are 5 compounds that have the ideal perovskite as their ground state.

Synthesis and Characterization

In order to test the validity of the computational results, KBaTeBiO₆ was synthesized. KNO₃, Ba(NO₃)₂, Te(OH)₂, and Bi(NO₃)₃·5 H₂O were used as the precursors for each element. A solution of each precursor was prepared separately in deionized water, except for Bi(NO₃)₃.5H₂O which was prepared in HNO₃ and water mixture (1:3 ratio of HNO₃:H₂O). An equimolar mixture solution with 0.1 M concentration of the precursors was then prepared in nitric acid. The precursor mixture was dried overnight (12 hours) in a muffle furnace at 100° C. After complete drying, the dried precursor powder (˜0.31 g) was annealed at high temperature for 6 hours (time after reaching the desired temperature).

Thermogravimetric analysis (TGA) was performed using thermogravimetric and differential thermal analyses (TGA/DTA) (TA Instruments, New Castle, Del.) to choose a proper temperature for annealing based on the decomposition profile of the precursors. The annealed powders were characterized to investigate crystal structure, optical properties (band gap) and elemental composition. Crystal structure information was obtained using an X-ray diffractometer (XRD, Bruker D8 Advance, Bruker, USA) in Bragg-Brentano geometry, configured with a 1.5418 Å Cu X-ray under an operating condition of 40 kV. Analysis of the XRD pattern and peak search was performed using the DIFFRACTION. SUITE Eva software. The absorption spectrum of the double perovskite (powder dispersed in water) was measured using a UV-Vis spectrophotometer (UV-2600, Shimadzu, USA) with an integrating sphere (ISR-2600 Plus, Shimadzu, USA) over 300-900 nm with a step size of 0.5 nm. Elemental composition was determined by field emission scanning electron microscopy—energy dispersive spectroscopy (FESEM, Nova NanoSEM 230), on powder samples. The accelerating voltage of 25 kV was used, which allowed the detection of heavy element, especially Bi.

Thermogravimetric Analysis

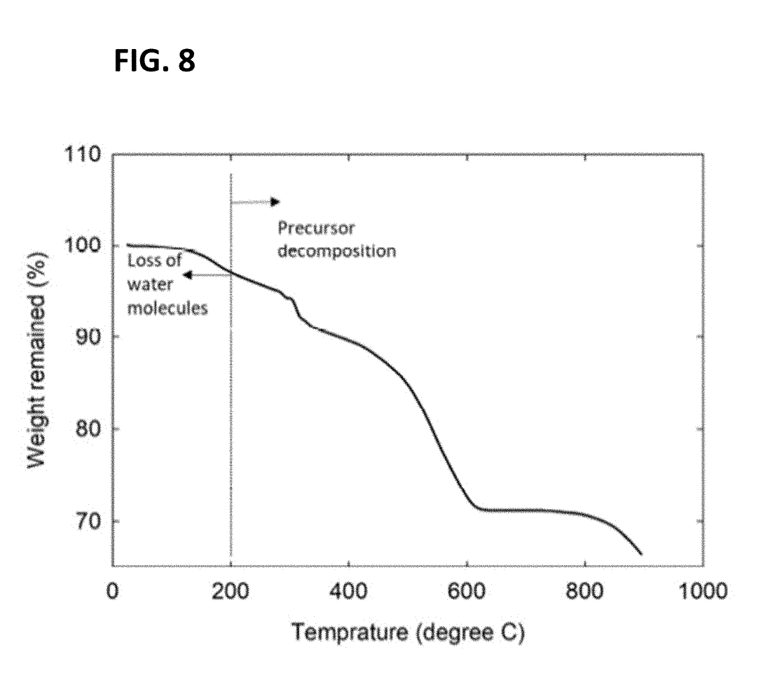

Thermogravimetric analysis (FIG. 8) on the mixed precursor powder shows the mass change in the temperature range of 200-650° C., consisting of initial slow mass loss (below 400° C.) and rapid mass loss (above 400° C.). The weight loss below 200° C. is generally caused by the desorption of physically and/or chemically adsorbed water in the sample, while the loss at higher temperatures results from the decomposition of barium, potassium, bismuth nitrates, telluric acid (thermal decomposition temperature in the range of 400-650° C.). Therefore, based on the TGA profile, we choose the two temperatures, 500° C. and 600° C., to transform the mixed precursors to the perovskite with desired stoichiometry.

Energy Dispersive Spectroscopy (EDS) Analysis

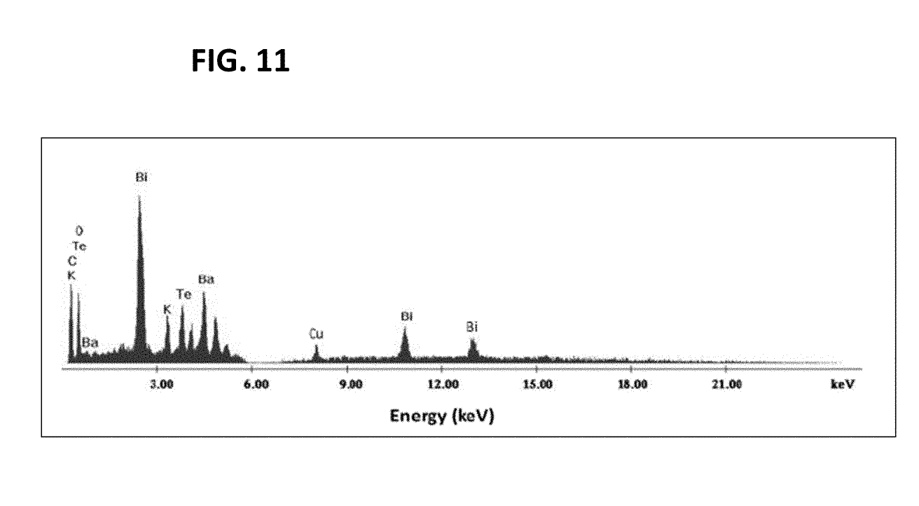

To confirm the elemental ratio in the KBaTeBiO₆, energy dispersive spectroscopy (EDS) was performed with KBaTeBiO₆ powder on Cu tape (see FIG. 11). A high accelerating voltage of 25 kV was applied to excite the Bi-L series. EDS measurements were performed at multiple sites. The elemental ratio was then calculated from the weight percent of the elements using the average for all the different sites. Subsequently, the average weight percent of the elements was normalized with respect to K (the element with the lowest quantity). The following ratios were observed for K:Ba:Te:Bi: 1 (±0.28): 1.55 (±0.29): 1.11 (±0.35): 1.17 (±0.35). The presence of high Bi, Te, and Ba compare to K suggests that the trace peaks in the XRD pattern might belong to Te—Bi mixed oxide and barium oxide. Moreover, the deficiency of K is attributed to the low molecular weight and hence high volatility of its precursor, which causes easy evaporation during the 6 hours of annealing.

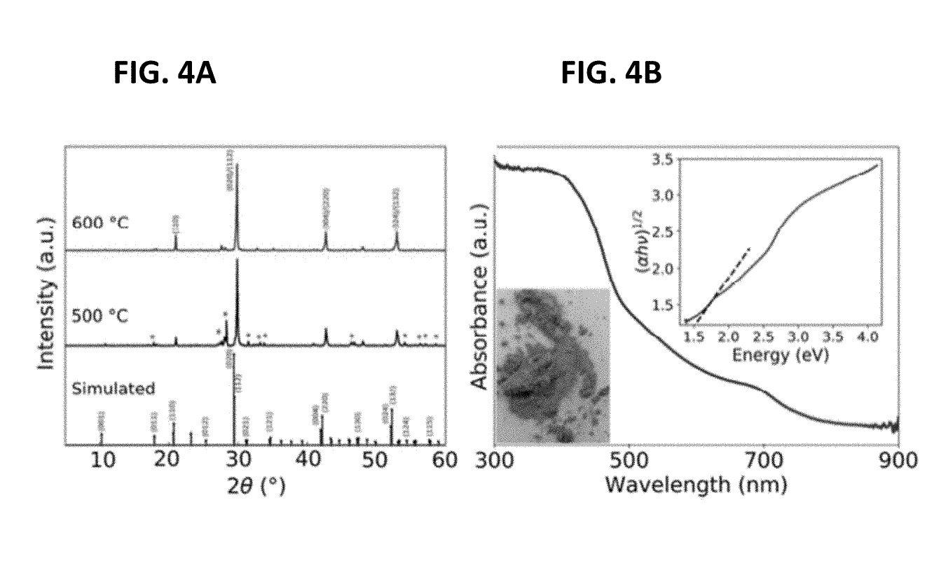

High-temperature annealing was required to obtain phase-pure material. FIG. 4A shows the X-ray powder diffraction (XRD) of the samples synthesized at 500 and 600° C., compared to the simulated XRD of KBaTeBiO₆. The sample synthesized at 500° C. contains unreacted precursors (marked with red asterisks) primarily consisting of mixed bismuth and tellurium oxides (Bi₂TeO₅, Bi₂Te₂O₇, Bi₆Te₂O₁₅, Bi₆Te₂O₁₃) and barium peroxide (BaO₂(H₂O₂)(H₂O)₂). By annealing the precursor powder at 600° C. for 6 hours, pure products were prepared. Thermogravimetric analysis on the mixed precursors is shown in FIG. 8.

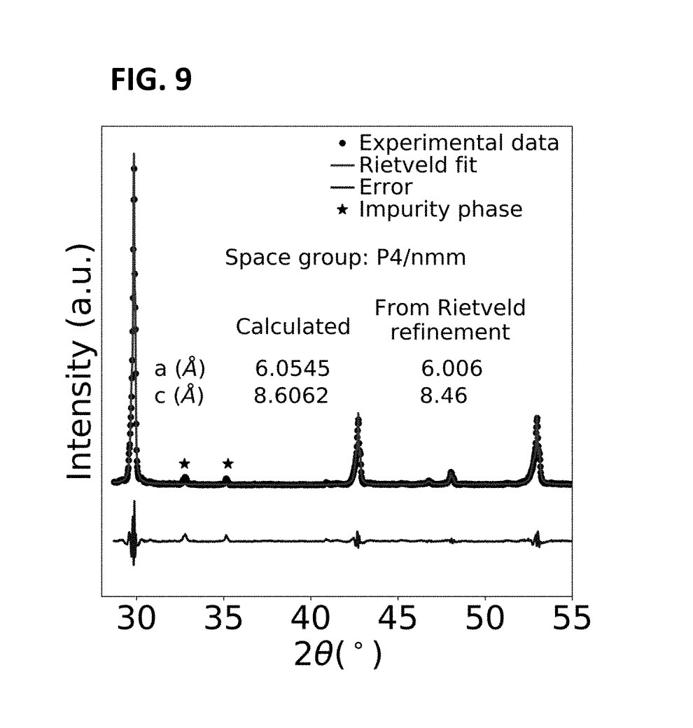

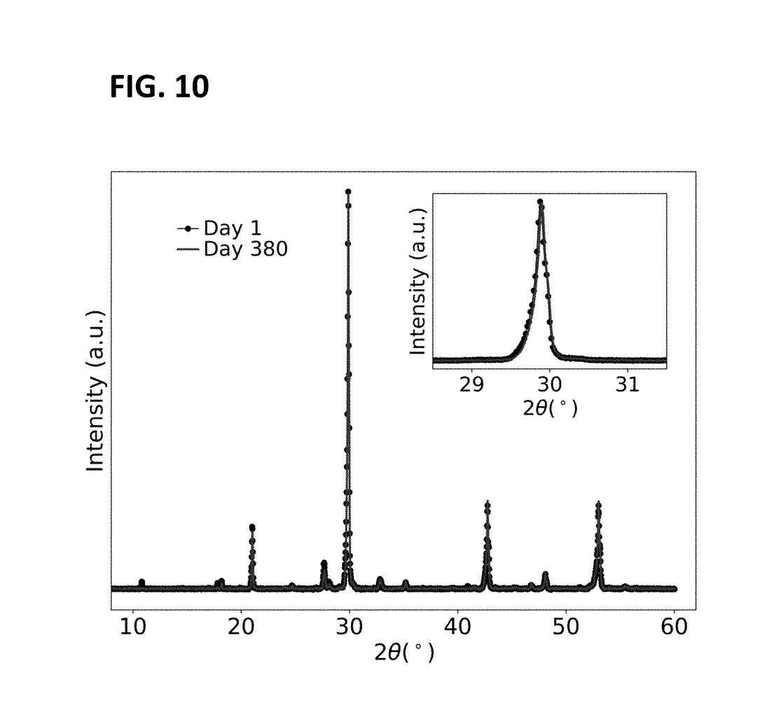

The sample annealed at 600° C. shows pure double perovskite KBaTeBiO₆, as shown in FIG. 4A. The major diffraction peaks at 21.02°, 29.86°, 42.87°, and 53.02° correspond to (110), convoluted (020)/(112), (004)/(220), and (024)/(132), respectively. Rietveld refinements of the experimental XRD data are shown in FIG. 9. As calculated from DFT, the ground state of KBaTeBiO₆ belongs to P4/mmm space-group symmetry. The calculated lattice parameters from DFT (a=b=6.0545 Å, c=8.6062 Å) are within 1.7% of the experimental lattice parameters (a=b=6.006 Å, c=8.46 Å), as obtained from Rietveld refinement. The slight overestimation of lattice parameters by DFT is expected due to the tendency of under-binding within the generalized gradient approximation (GGA) for the exchange-correlation functional. Importantly, the synthesized KBaTeBiO₆ samples are stable under ambient conditions. To investigate the stability of the material, the samples were stored under ambient conditions (30% relative humidity). XRD was performed again after 380 days (FIG. 10). No apparent changes in the XRD were observed in the sample on day 380. The elemental ratio analysis for KBaTeBiO₆ performed using energy dispersive spectroscopy (EDS) is shown in FIG. 11.

To ascertain the experimental optical gap of KBaTeBiO₆, the absorption spectrum of KBaTeBiO₆ was measured using a UV-Vis spectrophotometer. The absorption spectrum, as shown in FIG. 4B, indicates that the first major onset is around 730 nm followed by another sharp increase near 540 nm. The first major onset in the measured absorption spectrum is not very sharp due to the indirect nature of the band gap as confirmed by the DFT band structure, while the following sharp onset is expected to correspond to the first allowed direct optical transition. A Tauc plot was used to estimate the indirect band gap of KBaTeBiO₆ to be 1.5 eV (shown in the inset of FIG. 4B): (αhv)1/2 vs. hv; a being the absorption coefficient). The difference between the measured (1.5 eV) and the calculated HSE+SOC band gap (1.94 eV) could either be due to the fraction of Hartree-Fock exchange (α=0.25) used in the calculation, which is essentially a free-parameter, or due to the presence of cation disorder or the non-stoichiometry of the experimental compound.

This written description uses examples to disclose the subject matter herein, including the best mode, and also to enable any person skilled in the art to practice the subject matter in this disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A lead-free double perovskite having a formula of AA′BB′Oₙ, wherein A and A′ are the same or are different and are selected from the group consisting of alkali metals, alkaline earth metals, actinides, transition metals, post-transition metals and metalloids;
B and B′ are different and selected from the group consisting of alkali metals, alkaline earth metals, actinides, transition metals, post-transition metals and metalloids; and
n is a real number from 2 to 6.

2. The lead-free double perovskite according to claim 1, wherein B or B′ is Bi³⁺.

3. The lead-free double perovskite according to claim 1, wherein the sum of the oxidation states of A, A′ and B is 9.

4. The lead-free double perovskite according to claim 1, wherein A and A′ are different.

5. The lead-free double perovskite according to claim 1, wherein A and A′ are the same.

6. The lead-free double perovskite according to claim 1, wherein n=6.

7. The lead-free double perovskite according to claim 1, wherein the double perovskite has a formula of KBaTeBiO₆.

8. The lead-free double perovskite according to claim 1, wherein the double perovskite is other than RbMgTeBiO₆, NaCaTeBiO₆ or KCaTeBiO₆.

9. The lead-free double perovskite according to claim 1, wherein the band gap is from about 1.0 to about 3.0 eV.

10. The lead-free double perovskite according to claim 1, wherein the ΔH_{f} for the lead-free double perovskite is at or below 100 meV/atom for the ground state structure.

11. A semiconductor comprising a lead-free double perovskite having a formula of AA′BB′Oₙ,
wherein A and A′ are the same or are different and are selected from the group consisting of alkali metals, alkaline earth metals, actinides, transition metals, post-transition metals and metalloids;
B and B′ are different and selected from the group consisting of alkali metals, alkaline earth metals, actinides, transition metals, post-transition metals and metalloids; and
n is a real number from 2 to 6.

12. The semiconductor according to claim 11, wherein B or B′ is Bi³⁺.

13. The semiconductor according to claim 11, wherein the sum of the oxidation states of A, A′ and B is 9.

14. The semiconductor according to claim 11, wherein n=6.

15. The semiconductor according to claim 11, wherein the double perovskite has a formula of KBaTeBiO₆.

16. A photovoltaic cell comprising a lead-free double perovskite having a formula of AA′BB′ₙ,
wherein A and A′ are the same or are different and are selected from the group consisting of alkali metals, alkaline earth metals, actinides, transition metals, post-transition metals and metalloids;
B and B′ are different and selected from the group consisting of alkali metals, alkaline earth metals, actinides, transition metals, post-transition metals and metalloids; and
n is a real number from 2 to 6.

17. The photovoltaic cell according to claim 16, wherein B or B′ is Bi³⁺.

18. The photovoltaic cell according to claim 16, wherein the sum of the oxidation states of A, A′ and B is 9.

19. The photovoltaic cell according to claim 16, wherein n=6.

20. The photovoltaic cell according to claim 16, wherein the double perovskite has a formula of KBaTeBiO₆.
